(19) United States
(12) Patent Application Publication
(10) Pub. No.: US 2023/0180485 A1
(43) Pub. Date: Jun. 8, 2023

(54) UNIFORMLY PATTERNED TWO-TERMINAL DEVICES

(71) Applicant: International Business Machines Corporation, Armonk, NY (US)

(72) Inventors: Kevin W. Brew, Niskayuna, NY (US); Steven Michael McDermott, Wynantskill, NY (US); Nicole Saulnier, Slingerlands, NY (US); Muthumanickam Sankarapandian, Niskayuna, NY (US); Injo Ok, Loudonville, NY (US)

(21) Appl. No.: 17/540,389

(22) Filed: Dec. 2, 2021

(51) Int. Cl. H01L 27/24; H01L 27/22; H01L 49/02; H01L 43/08; H01L 43/12; H01L 45/00

(52) U.S. Cl. CPC H01L 27/2409; H01L 27/224; H01L 28/92; H01L 43/08; H01L 43/12; H01L 45/06; H01L 45/126; H01L 45/1675

(57) ABSTRACT

A two-terminal device comprises a bottom electrode. A device element is formed upon the bottom electrode. The two-terminal device also comprises a top electrode that is formed upon the device element. The bottom electrode and the top electrode are aligned. The bottom electrode and top electrode also have a same width and depth.

### BACKGROUND

The present invention relates to two-terminal devices, and more specifically, to two-terminal devices formed by subtractive etching.

Two-terminal devices include some non-volatile memories and some resistive elements. These devices typically include a two-terminal element (e.g., a memristor element, a heater paired with a phase-change material) formed on a first electrode and beneath a second electrode. The two-terminal element is typically formed by applying an excess amount of the two-terminal element material (e.g., hafnium oxide, germanium-antimony-tellurium) on top of the first electrode. At this point, the excess amount is typically etched away using subtractive etching until a two-terminal element of the desired dimensions remains.

In some use cases, two-terminal devices are formed in a pattern of many two-terminal devices (for example, a non-volatile memory chip with a grid of phase-change-memory cells). In these use cases, many two-terminal elements are etched simultaneously.

### SUMMARY

Some embodiments of the present disclosure can be illustrated as a two-terminal device. The two-terminal device comprises a bottom electrode and a device element formed on the bottom electrode. The two-terminal device also comprises a top electrode on the device element. The bottom electrode and top electrode are aligned and have a same width and depth.

Some embodiments of the present disclosure can also be illustrated as a method of forming a two-terminal device. The method comprises applying a bottom-electrode metal layer to a first set of underlying circuitry for the two-terminal device. The method also comprises a device-element material to the bottom electrode metal layer. The method also comprises etching excess device-element material. This results in a patterned device element. The method also comprises applying a top electrode metal layer to the device element. The method also comprises etching the bottom-electrode metal layer and the top-electrode metal layer using a single hard mask pattern. This results in a bottom electrode and a top electrode with a same width and depths.

Some embodiments of the disclosure can also be illustrated in a pattern of two-terminal device. The pattern comprises a first two-terminal device. The first two-terminal device comprises a first top electrode and a first bottom electrode. The first top electrode has the same width and depth as the first bottom electrode. The pattern comprises a second two-terminal device. The second two-terminal device comprises a second top electrode and a second bottom electrode. The second top electrode has the same width and depth as the second bottom electrode.

### BRIEF DESCRIPTION OF THE DRAWINGS

FIG. 1 illustrates a two-terminal device that comprises a top and bottom electrode that were etched simultaneously according to embodiments of the present disclosure.

FIG. 2A illustrates a first stage of forming a pair of two-terminal RAM cells according to embodiments of the present disclosure.

FIG. 2B illustrates a second stage of forming a pair of two-terminal RAM cells according to embodiments of the present disclosure.

FIG. 2C illustrates a third stage of forming a pair of two-terminal RAM cells according to embodiments of the present disclosure.

FIG. 2D illustrates a fourth stage of forming a pair of two-terminal RAM cells according to embodiments of the present disclosure.

FIG. 2E illustrates a fifth stage of forming a pair of two-terminal RAM cells according to embodiments of the present disclosure.

FIG. 2F illustrates a sixth stage of forming a pair of two-terminal RAM cells according to embodiments of the present disclosure.

FIG. 2G illustrates a seventh stage of forming a pair of two-terminal RAM cells according to embodiments of the present disclosure.

FIG. 2H illustrates an eighth stage of forming a pair of two-terminal RAM cells according to embodiments of the present disclosure.

FIG. 2I illustrates a ninth stage of forming a pair of two-terminal RAM cells according to embodiments of the present disclosure.

FIG. 2J illustrates a tenth stage of forming a pair of two-terminal RAM cells according to embodiments of the present disclosure.

FIG. 2K illustrates an eleventh stage of forming a pair of two-terminal RAM cells according to embodiments of the present disclosure.

FIG. 2L illustrates a twelfth stage of forming a pair of two-terminal RAM cells according to embodiments of the present disclosure.

FIG. 3 illustrates a method 300 of forming a pattern of two-terminal devices in accordance with embodiments of the present disclosure.

FIG. 4 illustrates an example computer system that could be used to perform some methods discussed in the present disclosure.

### DETAILED DESCRIPTION

Some two-terminal devices, such as analog memory cells (e.g., phase-change-memory cells) are particularly useful in the growing field of artificial-intelligence computing. Analog memory cells, in addition to being capable of being set to more than two states (e.g., a reset state and multiple set states with different read voltages), often require lower power than conventional memory devices.

Two-terminal devices, including analog non-volatile RAM cells, some resistor cells, and some capacitor cells (e.g., metal-insulator-metal capacitors) are often formed between a top electrode and a bottom electrode. In some formation processes, an excess amount of the material used to form a two-terminal device element (e.g., hafnium oxide in a resistive-RAM cell; insulator layer in a capacitor cell) is applied to a bottom electrode and substrate. The excess material is then etched away using subtractive wet etching. This subtractive wet etching results, in theory, in an element that is the proper size for the intended function of the cell.

For example, a phase-change memory cell (also referred to herein as a “PCM” cell) may have a target size and shape for the switching element in the cell (for example, a mass of phase-change material such as germanium-antimony-tellurium). This target size and shape may be chosen based on the cell's intended function. Specifically in this example, a phase-change material of the target size and shape may switch from a crystalline state to an amorphous state when a particular heating pattern is applied, and may switch back from the amorphous state to the crystalline state when a second particular heating pattern is applied.

However, if the switching element is smaller or larger, for example, than the target size/shape after subtractive etching, the switching element may not respond as expected. For example, a phase-change material in a PCM cell may require different heating patterns to switch between crystalline and amorphous states, a memristor in a resistive memory cell may require a different voltage to form a conductive filament, and a resistive element may provide a different resistance than expected. For this reason, controlling the rate at which a switching element (or resistive element) is etched during subtractive etching can be very important to ensuring that the cell in which the two-terminal device element is formed functions properly. Of note, a “two-terminal” device element is sometimes referred to herein simply as a “device element” for the sake of brevity. Thus, unless otherwise explicitly specified or clearly implicitly specified by the context in which the term is used, a “device element” as used herein is to be interpreted as a “two-terminal device element.”

In theory, controlling the etching rate of a single device element in a device with only one two-terminal device element is quite feasible. However, typical devices, such as memory modules, include patterns of many cells, such as RAM cells. In these devices, each device element is typically etched simultaneously. In some use cases, each device element should be etched at similar rates. However, in practice, many elements throughout a pattern are etched at significantly different rates due to the non-uniformity of the underlying circuitry to which those elements are connected.

For example, in a pattern of magnetic RAM cells, each switching element may be connected to a bit-line wire through a bottom electrode. However, the length of the bit-line wire connected to each switching element may differ based on, for example, where the cell that contains the switching element is located within the pattern of cells. Thus, the amount of metal connected to each switching element may differ significantly.

These variations in the amounts of metal can to which each cell is connected can create differences in “antenna effects” for each cell during subtractive etching. An antenna effect is, as used herein, describes an increased or decreased attraction to etching ions at a particular point in the pattern of switching/resistive cells. A connection to a large conductive wire, for example, can create a significantly higher attraction to etching ions than a connection to a short wire. In effect, the large conductive wire acts as an electrical sink for the etching ions, causing more etching to occur at devices that are connected to the large conductive wire.

For example, a device may include a chip with a pattern of resistive RAM (sometimes referred to herein as “ReRAM”) cells. Two particular ReRAM cells may be in different locations in the pattern, and the bit-line wiring connected to the first ReRAM cell may be five times as long as the bit-line wire connected to the second ReRAM cell. As a result, the longer bit-line wire may create a significant attractive effect (i.e., an antenna effect) while the switching elements of the ReRAM cells (e.g., the memristors) are being etched. In other words, the switching element in the first ReRAM cell may be etched significantly faster than the switching element in the second ReRAM cell. Thus, at the end of the etching process, the memristor in the first ReRAM cell may be significantly thinner than in the second. This may, in turn, lower the current necessary to create a conductive filament in the first ReRAM cell or reduce the switching voltage of the first ReRAM cell as compared to the second ReRAM cell.

In other words, non-uniformity of the underlying wiring to which two-terminal device elements are connected can, in mild cases, cause non-uniformity in the performance of the resulting structures that contain those device elements. In minor cases, this non-uniformity may only have small effects on the overall performance of the device. For example, in theory, even though the switching elements in two PCM cells may be of slightly different thicknesses, they may still both switch between crystalline and amorphous states when the same heating patterns are applied to both cells.

However, even in those particularly mild cases, performance of the cells may not be optimal. For example, even though the two PCM cells discussed above may both switch from the crystalline to amorphous state when a first heating pattern is applied, one of those PCM cells may switch significantly faster if a second heating pattern were applied and the other of those. PCM cells may switch significantly faster if a third heating pattern were applied.

Further, in less mild cases, slight differences in the etched device elements may cause inconsistent performance that may require certain cells to be switched with different voltages, for example. In other words, while both cells may function, there may be no single voltage (or heating pattern) that could switch both cells. In some cases, therefore, a memory controller may need to store, for example, switching voltages of many non-uniform cells in a device.

Further, in extreme cases, the non-uniformity in etch rates between multiple devices can lead to one or more device becoming completely non-functional. Referring again to the device with two PCM cells above can illustrate. In some instances, the phase-change material of the first PCM cell may be etched so much faster than the phase-change material of the second PCM cell that, by the time the phase-change-material of the second PCM cell was etched sufficiently to be functional, the phase-change-material of the first PCM cell may have been etched away completely, resulting in a memory cell with no switching element. In other words, in some cases, difference in etching rates between two cells may result in at least one of the cells being completely non-functional.

Some embodiments of the present disclosure address the above issues by shorting the two-terminal device elements of two-terminal devices together until after those device elements have been etched. For example, rather than patterning the bottom electrodes of the RAM cells in a group of RAM cells, some embodiments of the present disclosure form dielectric and device elements on the bottom-electrode metal layer without first forming that metal layer into distinct electrodes. As a result, all device elements in the pattern are connected together to the same underlying circuitry (e.g., bit-line or word-line wiring). As a result, the metal in that underlying circuitry is less able to form antenna effects in any given device element or group of device elements.

Further, because the bottom-electrode metal layer acts as an additional sink for the etchant ions, which dilutes any remaining antenna effects that the particular geometry of the underlying wiring near a particular cell may contribute. In other words, the bottom-electrode metal layer may help to further equalize the etching rates throughout the cells of the pattern. In fact, the added metal between the cells of the pattern, distributed evenly throughout the cells, may increase the overall rate of etching throughout the pattern. Thus, a secondary benefit of some embodiments of the present disclosure is that etching may occur slightly faster throughout the pattern.

Once the device elements of a device are etched to the desired size and shape, a top-electrode metal layer may be applied throughout the pattern. Etching masks may be applied to the cells of that top-electrode metal layer, and the top electrode and bottom electrode may then be etched simultaneously. In other words, each of the top electrode and bottom electrode may be patterned simultaneously using the same etch mask. Thus, a secondary benefit of some embodiments of the present disclosure is a reduction in the number of etch masks that need to be applied throughout the overall process of forming the cells, as well as a reduction in the number of etching procedures. Finally, as a result of being etched with the same mask, the top electrode and bottom electrode may be, depending on the etching process used, nearly perfectly aligned. This may result in the top electrode and bottom electrode having the same width and depth.

As used herein, a top and bottom electrode having a “same” width and depth may not actually require identical dimensions. Rather, the precise level of similarity may depend on the etching process used on the electrodes; some etching processes etch a slight slope into a device rather than etching perfectly down into the device. For this reason, a hole or via etched through a top electrode and bottom electrode may have a slight slope, such as 80 degrees, rather than 90 degrees. This may cause the bottom electrode to be slightly larger, in width and depth, than the top electrode, even though both electrodes may have been etched simultaneously using the same etch mask. However, to the extent that the differences in width and depth between the top electrode and bottom electrode are small enough (or of a character) that those differences are attributable to the etching process used, rather than to the top and bottom electrodes being etched in different processes or with different etch masks, those electrode may be described herein as exhibiting a “same” width and depth.

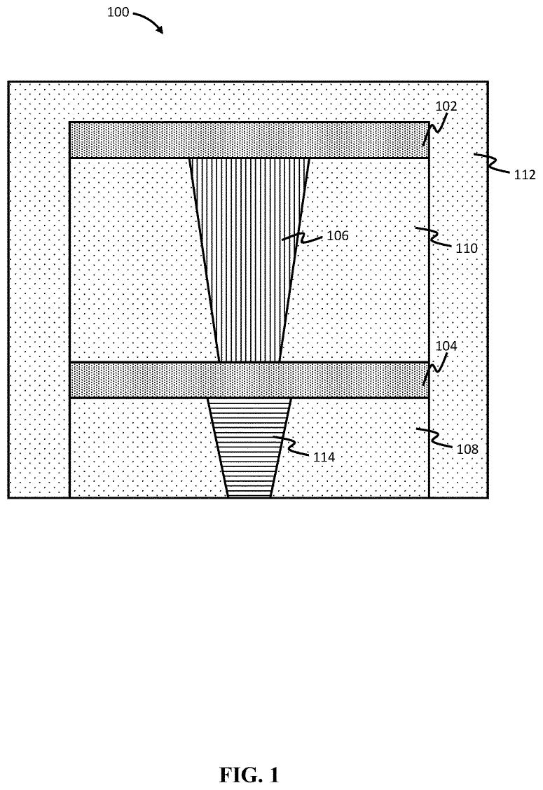

For example, FIG. 1 illustrates a two-terminal device 100 that comprises a top electrode 102 and bottom electrode 104 that were etched simultaneously according to embodiments of the present disclosure. Two-terminal device 100 may be, for example, a resistor structure, a metal-insulator-metal capacitor (sometimes referred to as an “MIMCAP”) or a non-volatile analog memory such as a phase-change-memory cell, a ferroelectric RAM (sometimes referred to as a FeRAM) cell, a ReRAM cell, a conductive-bridging RAM cell, an electrochemical RAM cell, or others. Thus, device element 106 may represent, for example, a memory structure such as a memristor, a combination of a heater and phase-change material, or a material with a pre-determined resistivity for use in a resistor.

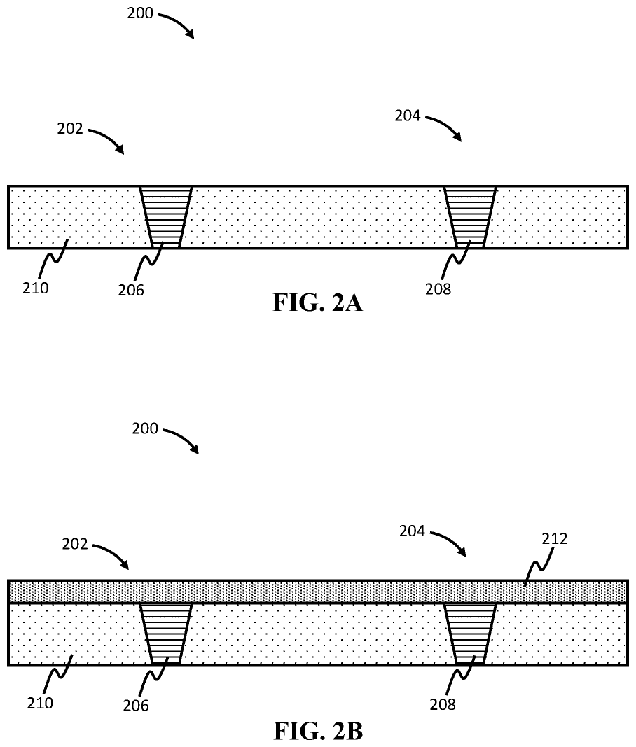

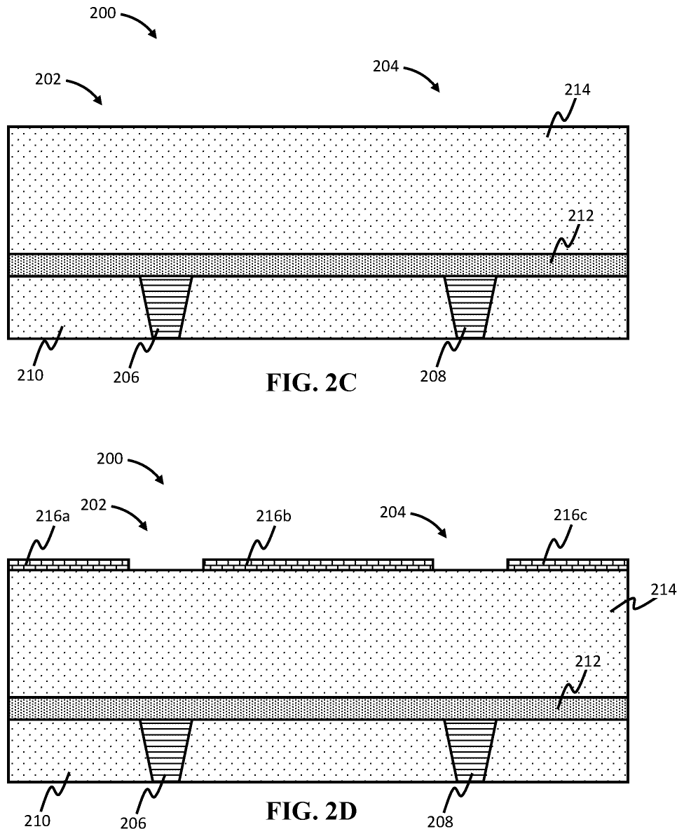

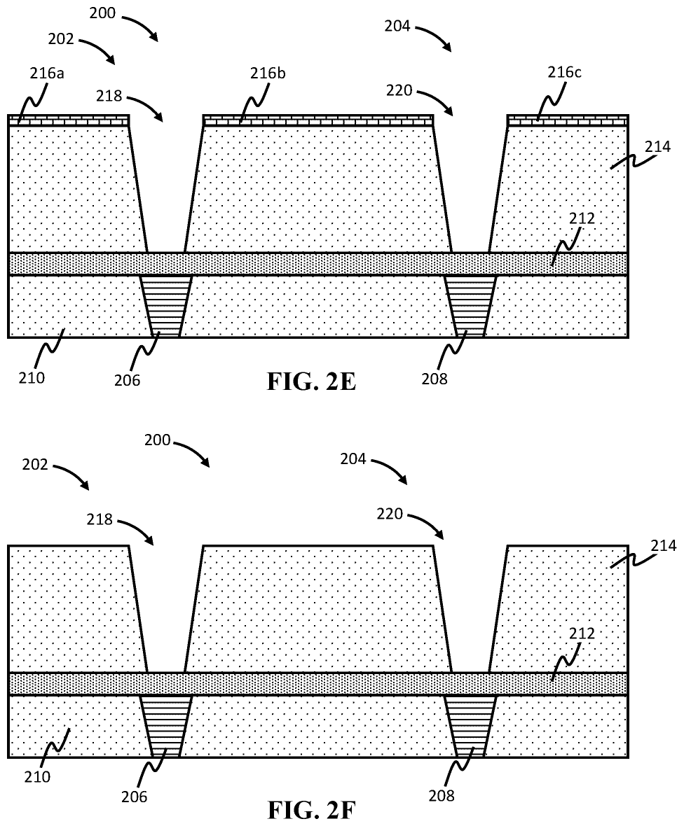

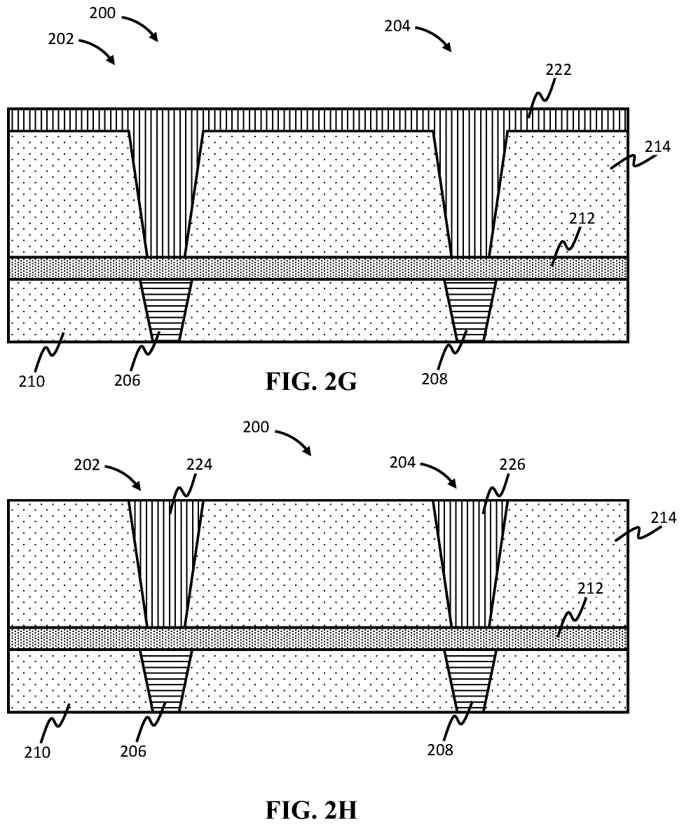

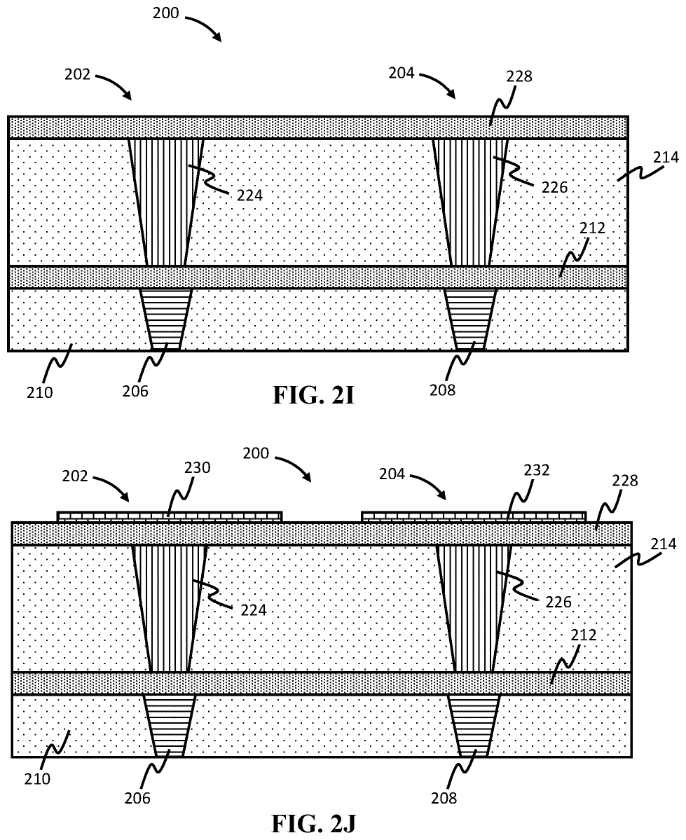

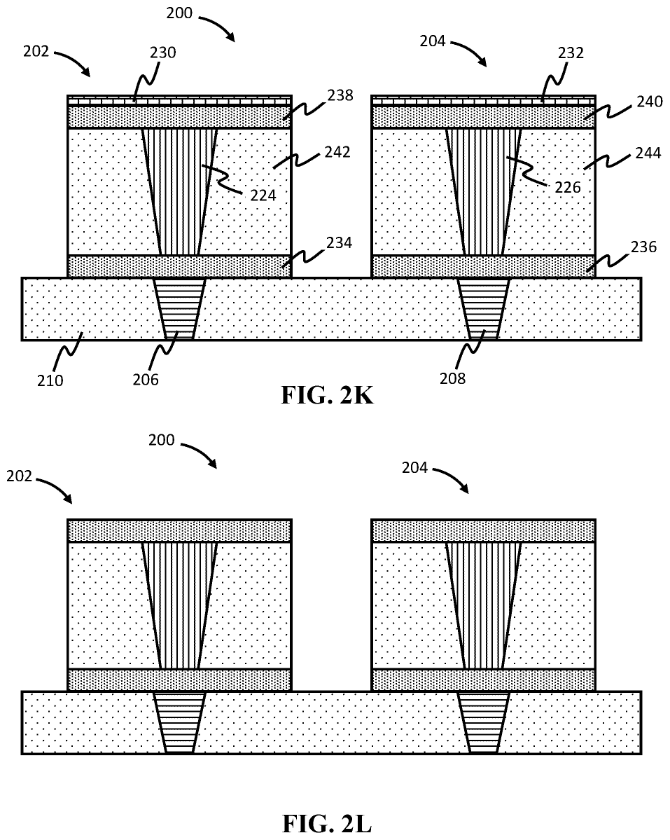

Two-terminal device also contains dielectric layers 108, 110, and 112. Dielectric layers 108, 110, and 112 may be formed of the same dielectric material or a different dielectric material. Example dielectric materials include silicon dioxide, silicon nitride, and hafnium dioxide. Of note dielectric 112 extends past 108 towards the bottom of FIG. 1, as illustrated. This may be useful, for example, in use cases in which underlying circuitry 114 and dielectric layer 108 should be separated from other portions of the pattern in which two-terminal device 100 is incorporated. For example, if two-terminal device 100 is a PCM cell and underlying circuitry 114 is composed of a metal nitride, top electrode 102 may need to be isolated from underlying circuitry 114. However, in other use cases, dielectric layer 108 may continue throughout the pattern, and dielectric layer 112 may terminate at the surface of dielectric layer 108. Such an embodiment is illustrated in FIG. 2L.

Top electrode 102 and bottom electrode 104 are illustrated as having the same width (i.e., the axis that spans from the left side of the figure to the right side of the figure). This suggests that top electrode 102 and bottom electrode 104 were patterned simultaneously using the same etch mask and after device element 106 was etched. In other words, rather than etching the bottom-electrode metal layer into bottom electrode 104 before depositing dielectric layer 110 and device element 106, the bottom-electrode metal layer may have been maintained until the etching of a top-electrode metal layer into top electrode 102. This may be beneficial because it avoids a need for applying an etch mask dedicated solely to etching bottom electrode 104, and because it reduces the number of etching processes needed for the electrode layers by 1.

Maintaining the bottom-electrode metal layer until the etching of top electrode 102 may also reduce non-uniformity between device element 106 and other two-terminal device elements within the same pattern. To illustrate, two-terminal device 100 also contains underlying circuitry 114, which may represent bit-line or word-line wiring, for example. Device element 106 is connected to underlying circuitry 114 through bottom electrode 104. Thus, the connection to underlying circuitry 114 and bottom electrode 104 may have affected the rate of etching of device element 106 during formation of two-terminal device 100.

However, as discussed, if bottom electrode 104 was unpatterned during the etching of device element 106, bottom electrode 104 would have, at that time, been in the form of a bottom-electrode metal layer. Thus, other two-terminal device elements in the same pattern may have also been connected to that bottom-electrode metal layer and the same underlying circuitry 114 to which device element 106 is connected. Thus, any affects created by that bottom-electrode metal layer and underlying circuitry 114 may have affected the etch rates of device element 106 and those other two-terminal device elements to the same degree. This, therefore, may have prevented non-uniformity between the device elements.

FIGS. 2A-2L depict, for the sake of understanding, an example process of forming multiple two-terminal RAM cells in a pattern 200 of two-terminal RAM cells. The process includes shorting each cell to the same bottom-electrode metal layer until after the etching of the switching elements within each cell. It is of note that the dimensions and positions of each cell with respect to the other cell, with respect to the structures within each cell, and with respect to pattern 200 as a whole is presented in an abstract manner for the purposes of understanding.

Thus, for example, while each RAM cell presented in FIGS. 2A-2L are illustrated as located immediately next to each other, in some embodiments the RAM cells may be located in significantly different positions in pattern 200. As a result, the underlying circuitry of each RAM cell may be very different, and may thus tend to cause significantly different antenna affects unless formed through the processes of the present disclosure.

Further, while FIGS. 2A-2L are discussed as taking the form of RAM cells (e.g., ReRAM cells, PCM RAM cells, MRAM cells), the stages disclosed in FIGS. 2A-2L could be applied to processes of forming other types of two-terminal devices in a pattern, such as resistor devices. Finally, it is of note that the stages depicted in FIGS. 2A-2L could be performed by a computer system, such as computer system 401, that is automatically or semi-automatically forming a pattern of two-terminal devices (for example, a computer system automatically forming a NVRAM chip).

FIG. 2A illustrates a first stage of forming a pair of two-terminal RAM cells 202 and 204. At this stage, the discrete forms of each RAM cell 202 and 204 is not apparent. Each RAM cell is connected to underlying circuitry 206 and 208, which may take the form, for example, of a bit wire or a connection to a bit wire. For this reason, each of underlying circuitry may also individually be referred to herein as a set of underlying circuitry. Each of underlying circuitry 206 and 208 have been formed within dielectric layer 210.

FIG. 2B illustrates a second stage of forming two-terminal RAM cells 202 and 204. In FIG. 2B, each a bottom-electrode metal layer 212 has been deposited onto dielectric layer 210 and underlying circuitry 206 and 208. As such, an electrical connection is formed between both of underlying circuitry 206 and underlying circuitry 208 and bottom-electrode metal layer 212. In other words, bottom-electrode metal layer 212 is shorting underlying circuitry 206 and underlying circuitry 208 to each other. Further, bottom-electrode metal layer 212 may have been applied throughout the entirety of pattern 200, in which case bottom-electrode metal layer may be shorting all RAM cells in pattern 200 together.

FIG. 2C illustrates a third stage of forming two-terminal RAM cells 202 and 204. In FIG. 2C, dielectric layer 214 has been deposited on top of bottom-electrode metal layer 212. Dielectric layer 214 spans over at least both RAM cells 202 and 204, but may also have been deposited throughout the entirety of pattern 200.

FIG. 2D illustrates a fourth stage of forming two-terminal RAM cells 202 and 204. In FIG. 2D, hardmasks 216a-216c have been formed on dielectric layer 214. While hardmasks 216a-216c appear to be separate structures, they may all be the same physical structure in some embodiments. However, hardmasks 216a-216c appear to be separate structures in FIG. 2D due to the cross-sectional nature of FIG. 2D. Hardmasks 216a-216c are formed to prevent unwanted etching of some areas of dielectric layer 214 during later stages. Thus, the composition of hardmasks 216a-216c may depend on the type of etching used, for example, when forming wells for switching elements in RAM cells 202 and 204.

FIG. 2E illustrates a fifth stage of forming two-terminal RAM cells 202 and 204. In FIG. 2E, wells 218 and 220 have been etched within dielectric layer 214. As illustrated, these wells may have been formed by a dry etching processes, as hardmasks 216a-216c do not overlap wells 218 or 220. However, in some embodiments a wet etching process may have been used, in which case hardmasks 216a-216c may have been formed wider to account for the etching beneath their edges, causing wells 218 and 220 to form partially under hardmasks 216a-216c.

FIG. 2F illustrates a sixth stage of forming two-terminal RAM cells 202 and 204. In FIG. 2F, hardmasks 216a-216c have been removed. Well 218 remains in RAM cell 202 and well 220 remains in RAM cell 204. Bottom-electrode metal layer 212 is exposed at the bottom of both wells 218 and 220, and thus is exposed in both RAM cells 202 and 204. In some embodiments, bottom-electrode metal layer 212 is exposed to a well in each RAM cell throughout pattern 200.

FIG. 2G illustrates a seventh stage of forming two-terminal RAM cells 202 and 204. In FIG. 2G, wells 218 and 220 have been filled with switching-element material 222. The composition of switching-element material 222 may vary based on the eventual design of RAM cells 202 and 204. For example, if RAM cells 202 and 204 were resistive RAM cells, switching-element material 222 may take the form of hafnium oxide.

Alternatively, if RAM cells 202 and 204 phase-change-memory cells, switching-element material 222 may take the form of a phase-change material and a heating element. For example, a top portion of switching-element material 222 may take the form of a phase-change material such as germanium-antimony-tellurium (sometimes referred to herein as “GST”). A bottom portion of switching-element material closest to bottom electrode 212 may take the form of a heater element such as tin nitride.

Similarly, if RAM cells 202 and 204 were magnetoresistive RAM (also referred to herein as “MRAM”) cells, switching-element material 222 may take the form of a multi-layer magnetic tunnel junction (e.g., two magnets separated by an insulator). For example, a top portion of switching-element material may take the form of a free layer (e.g., cobalt-iron-beryllium), a middle portion may take the form of a tunnel insulator (e.g., magnesium oxide), and a bottom portion may take the form of a fixed/pinned layer (e.g., cobalt-iron-beryllium).

Regardless of the form of RAM cells 202 and 204, an excess portion of switching-element material 222 has been applied, forming a layer on top of dielectric layer 214. If, for example, RAM cells 202 and 204 were resistive RAM cells, the excess material may be hafnium oxide. If RAM cells 202 and 204 were phase-change-memory cells, the excess material may be GST. If RAM cells 202 and 204 were MRAM cells, the excess material may be cobalt-iron-beryllium (sometimes referred to herein as CoFeBe).

Thus, FIG. 2H illustrates an eighth stage of forming two-terminal RAM cells 202 and 204. In FIG. 2H, the excess portion of switching-element material 222 has been etched away by subtractive etching. Thus, as illustrated, only the portion of the switching-element material that was formed within wells 218 and 220 remain in cells 202 and 204. This has resulted in switching element 224 in RAM cell 202 and switching element 226 in RAM cell 204.

Both these switching elements 224 and 226 are connected to bottom-electrode metal layer 212, which itself is connected to both underlying circuitry 206 and underlying circuitry 208. Thus, bottom-electrode metal layer 212 effectively shorts switching elements 224 and 226, underlying circuitry 206, and underlying circuitry 208 together. This may have prevented differences between underlying circuitry 206 and underlying circuitry 208 from causing significantly different antenna effects at RAM cells 202 and 204 during the etching of switching elements 224 and 226.

In other words, even if, in theory, underlying circuitry 206 contained 10 times as much conductive mass as underlying circuitry 208, the antenna effects of those conductive masses on RAM cells 202 and 204, and thus the etch rates of switching elements 224 and 226, should be relatively uniform. As a result, switching elements 224 and 226 are now largely uniform, and are thus depicted with the same heights (i.e., the same distance spanning away from bottom-electrode metal layer 212). For this reason, switching elements 224 and 226 should have very similar, if not identical performance. This may be true if memory cells 202 and 204 were indeed located adjacent to each other within pattern 200, or if they were located in significantly different positions in pattern 200.

2I illustrates a ninth stage of forming two-terminal RAM cells 202 and 204. In this ninth stage, top-electrode metal layer 228 has been formed on switching elements 224 and 226 and on dielectric layer 214. Like bottom-electrode metal layer 212, top-electrode metal layer 228 may have been formed throughout pattern 200 (i.e., on all active and dummy cells in pattern 200). In some embodiments, top-electrode metal layer 228 may be of the same composition as bottom-electrode metal layer 212. Top-electrode metal layer 228 may be composed of, for example, tin nitride, tantalum nitride, or ruthenium.

FIG. 2J illustrates a tenth stage of forming RAM cells 202 and 204. In this tenth stage, etch hardmasks 230 and 232 have been applied to cells 202 and 204. Etch hardmasks 230 and 232 may be designed to protect the structures of RAM cells 202 and 204 from the etchant used to pattern top-electrode metal layer 228 and bottom-electrode metal layer 212 into top and bottom electrodes. Thus, the composition of etch hardmasks 230 and 232 may depend on, for example, the etch process used. A dry etch process may be used, for example, to produce etch wells that are largely vertical, which may be necessary to protect the structures of RAM cells 202 and 204. In this case, hard masks 230 and 232 may be formed of silicon carbide, tantalum pentoxide, or aluminum nitride, for example. If a wet etch process is used, hard masks 230 and 232 may be formed of silicon nitride, for example.

FIG. 2K illustrates an eleventh stage of forming RAM cells 202 and 204. FIG. 2K depicts RAM cells 202 and 204 after bottom electrodes 234 and 236 and top electrodes 238 and 240 have been patterned by an etching process. This process has also patterned dielectric layers 242 and 244. The structures of RAM cells 202 and 204 that were beneath hardmasks 230 and 232 were not etched by this process. As a result, RAM cells 202 and 204 are no longer shorted together; they may be electrically separated, and may act as independent cells.

Finally, FIG. 2L depicts a twelfth stage of forming RAM cells 202 and 204. In this twelfth stage, hardmasks 230 and 232 have been removed. At this point, dielectric layers may be added to RAM cells 202 and 204, and top circuitry (e.g., word lines) may be added to the cells to of pattern 200.

Of note, the stages illustrated in FIG. 2L are intended to be examples of one method by which a two-terminal device in accordance with the embodiments of the present disclosure may be formed. However, in some embodiments a two-terminal device may be formed through other methods while still remaining within the reasonable bounds of the present disclosure. For example, in some embodiments a device element may be formed on a bottom-electrode metal layer before the formation of a surrounding dielectric.

This may resemble, for example, patterning a device element into a pillar on top of bottom-electrode metal layer 212 after FIG. 2B but before the application of dielectric layer 214 in FIG. 2C. Once this device element has been patterned on bottom-electrode metal layer 212, a dielectric layer such as dielectric layer 214 could then be formed around the device element.

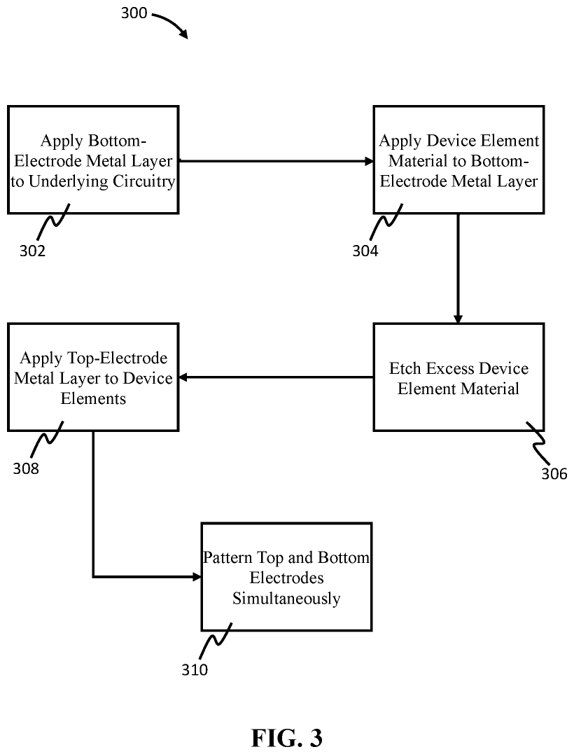

For the sake of understanding, FIG. 3 illustrates a method 300 of forming a pattern of two-terminal devices in accordance with embodiments of the present disclosure. It is of note that method 300 is presented as a generalized process by which many structures of the embodiments of the present disclosure may be formed. Thus, method 300 could be used to form a pattern of various two-terminal non-volatile RAM cells or two-terminal resistor devices. The specifics of each operation of method 300 may vary based upon the precise implementation of the method and the properties of the devices formed.

It is of further note that the stages depicted in FIGS. 2A-2L could be performed by a computer system, such as computer system 401, that is automatically or semi-automatically forming a pattern of two-terminal devices (for example, a computer system automatically forming one or more resistor devices within a pattern of devices).

Method 300 begins in block 302, in which a bottom-electrode metal layer is applied upon underlying circuitry of the pattern. In some embodiments, this bottom-electrode metal layer may also be formed upon a dielectric layer in which the underlying circuitry is embedded. Block 302 may, for example, resemble FIGS. 2A and 2B.

Method 300 continues in block 304, in which two-terminal device-element material is formed in the pattern upon the bottom-electrode metal layer. Block 304 may include, for example, forming a dielectric layer upon the bottom-electrode metal layer, etching wells within the bottom electrode metal layer, and applying the switching/resistive material upon the bottom-electrode metal layer that is exposed within those wells. Block 304 may resemble, for example, FIGS. 2C-2G.

Block 304 may also include, for example, forming a pillar of device-element material upon the bottom-electrode metal layer. In this example, a dielectric layer may then be formed around the device-element material.

It is of note that the device-element material that is formed in block 304 may depend upon the design of the two-terminal devices that are being formed by method 300. For example, as discussed with respect to FIG. 2G, the device-element material may be formed of several portions.

If the two-terminal devices being formed are resistive RAM cells, for example, the material may be a single layer of hafnium oxide (or a layer of hafnium oxide with a buffer layer on top). If the devices are phase-change memory cells, for example, the material may compose a heater element with a phase-change material on top. If the two-terminal devices being formed are magnetoresistive RAM cells, for example, the material may be a 3-layer magnetic tunnel junction. If, on the other hand, the two-terminal devices being formed are resistor devices, for example, the material may be a resistive material with a target resistance, such as a dielectric.

It is of note that, as illustrated in and discussed with respect to FIGS. 2G and 2H, block 304 occurs before the bottom-electrode metal layer that was applied in block 302 has been patterned (e.g., etched) into individual bottom electrodes for each two-terminal device. Thus, the bottom-electrode metal to which the switching/resistive material that is applied in block 304 may make electrical contact with the switching/resistive material and the underlying circuitry of each two-terminal device. For this reason, each switching/resistive material in each well of the pattern may be considered shorted together electrically.

Also of note, block 304 includes applying excess device-element material. This may be necessary to ensure that sufficient material is applied for all two-terminal devices in the pattern to be fully formed. For this reason, method 300 continues with block 306 in which excess switching/resistive material is etched away. Block 306 may utilize, for example, a subtractive etching process.

However, because, as discussed above, the switching/resistive material of each two-terminal device in the pattern is effectively shorted together, the etch rate of the switching/resistive material may be relatively constant throughout the pattern of two-terminal devices. In other words, the antenna effects of the underlying circuitry that is connected to each two-terminal device in the pattern may be distributed throughout the entire pattern of two-terminal devices. This may result in significantly uniform etching of the device-element material throughout the pattern of two-terminal devices, resulting in turn in uniform device elements. Block 304 may resemble, therefore, FIG. 2H.

Method 300 continues in block 308 in which a top-electrode metal layer is applied to the two-terminal device elements that were patterned in block 306. In some embodiments, this top-electrode metal layer may also be applied to a dielectric layer into which the device elements have been embedded. Further, this top-electrode metal layer may, in some embodiments, be applied to the device elements of all two-terminal devices throughout the pattern of two-terminal devices. Block 308 may resemble FIG. 2I.

Method 300 continues in block 310 in which the bottom and top electrodes are patterned simultaneously. In some embodiments, block 310 may include applying a set of hardmasks in a pattern on the top-electrode metal layer. An etching process may then etch both the top-electrode metal layer and the bottom-electrode metal layer into a pattern of top and bottom electrodes that matches that hard-mask pattern. The top and bottom electrodes for each individual two-terminal device may, therefore, be aligned and have the same width and depth dimensions (e.g., to the left and right of FIG. 1 and into and out of the paper on which FIG. 1 is printed). Block 310 may resemble FIGS. 2J-2L.

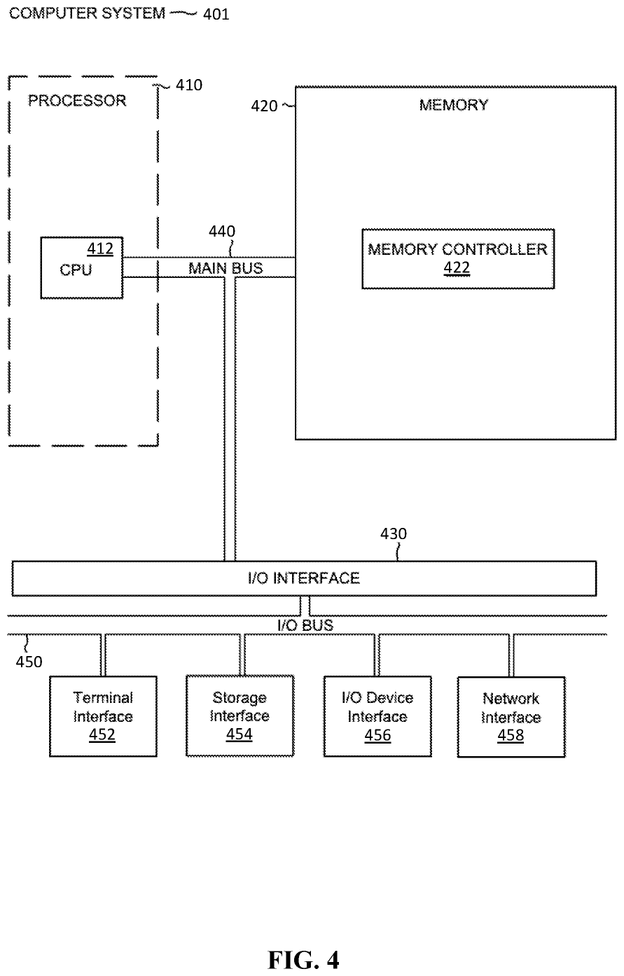

FIG. 4 depicts the representative major components of an example Computer System 401 that may be used in accordance with embodiments of the present disclosure. The particular components depicted are presented for the purpose of example only and are not necessarily the only such variations. The Computer System 401 may include a Processor 410, Memory 420, an Input/Output Interface (also referred to herein as I/O or I/O Interface) 430, and a Main Bus 440. The Main Bus 440 may provide communication pathways for the other components of the Computer System 401. In some embodiments, the Main Bus 440 may connect to other components such as a specialized digital signal processor (not depicted).

The Processor 410 of the Computer System 401 may include one or more CPUs 412.

The Processor 410 may additionally include one or more memory buffers or caches (not depicted) that provide temporary storage of instructions and data for the CPU 412. The CPU 412 may perform instructions on input provided from the caches or from the Memory 420 and output the result to caches or the Memory 420. The CPU 412 may include one or more circuits configured to perform one or more methods consistent with embodiments of the present disclosure. In some embodiments, the Computer System 401 may contain multiple Processors 410 typical of a relatively large system. In other embodiments, however, the Computer System 401 may contain a single processor with a singular CPU 412.

The Memory 420 of the Computer System 401 may include a Memory Controller 422 and one or more memory modules for temporarily or permanently storing data (not depicted). In some embodiments, the Memory 420 may include a random-access semiconductor memory, storage device, or storage medium (either volatile or non-volatile) for storing data and programs. The Memory Controller 422 may communicate with the Processor 410, facilitating storage and retrieval of information in the memory modules. The Memory Controller 422 may communicate with the I/O Interface 430, facilitating storage and retrieval of input or output in the memory modules. In some embodiments, the memory modules may be dual in-line memory modules.

The I/O Interface 430 may include an I/O Bus 450, a Terminal Interface 452, a Storage Interface 454, an I/O Device Interface 456, and a Network Interface 458. The I/O Interface 430 may connect the Main Bus 440 to the I/O Bus 450. The I/O Interface 430 may direct instructions and data from the Processor 410 and Memory 420 to the various interfaces of the I/O Bus 450. The I/O Interface 430 may also direct instructions and data from the various interfaces of the I/O Bus 450 to the Processor 410 and Memory 420. The various interfaces may include the Terminal Interface 452, the Storage Interface 454, the I/O Device Interface 456, and the Network Interface 458. In some embodiments, the various interfaces may include a subset of the aforementioned interfaces (e.g., an embedded computer system in an industrial application may not include the Terminal Interface 452 and the Storage Interface 454).

Logic modules throughout the Computer System 401—including but not limited to the Memory 420, the Processor 410, and the I/O Interface 430—may communicate failures and changes to one or more components to a hypervisor or operating system (not depicted). The hypervisor or the operating system may allocate the various resources available in the Computer System 401 and track the location of data in Memory 420 and of processes assigned to various CPUs 412. In embodiments that combine or rearrange elements, aspects of the logic modules' capabilities may be combined or redistributed. These variations would be apparent to one skilled in the art.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A two-terminal device comprising:
a bottom electrode;
a device element formed on the bottom electrode; and
a top electrode formed on the device element;
wherein the bottom electrode and top electrode are aligned and have a same width and depth.

2. The two-terminal device of claim 1, wherein the bottom electrode is formed upon underlying circuitry for the two-terminal device.

3. The two-terminal device of claim 1, wherein the two-terminal device is a phase-change memory cell, and the device element comprises a heating element and a phase-change material.

4. The two-terminal device of claim 1, wherein the two-terminal device is a resistive RAM cell, and the device element comprises a memristor.

5. The two-terminal device of claim 1, wherein the two-terminal device is a magnetoresistive RAM cell, and the device element comprises a magnetic tunnel junction.

6. The two-terminal device of claim 1, wherein the two-terminal device is a resistor device, and wherein the device element comprises a resistive material.

7. The two-terminal device of claim 1, wherein the two-terminal device is a metal-insulator-metal capacitor device, and wherein the device element comprises an insulative material.

8. A method of forming a two-terminal device, the method comprising:
applying a bottom-electrode metal layer to a first set of underlying circuitry for the two-terminal device;
applying a device-element material to the bottom-electrode metal layer;
etching excess device-element material, resulting in a patterned device element;
applying a top-electrode metal layer to the device element;
etching the bottom-electrode metal layer and the top-electrode metal layer using a single hard-mask pattern, resulting in a bottom electrode and a top electrode with a same width and depth.

9. The method of claim 8, wherein the bottom-electrode metal layer electrically connects the device element to a second device element of a second two-terminal device.

10. The method of claim 9 wherein the etching the excess device-element material at the two-terminal device occurs at the same rate as the etching the excess device-element material at the second two-terminal device.

11. The method of claim 10, wherein the second two-terminal device connects to a second set of underlying circuitry, and wherein a first mass of conductive metal within the first set of underlying circuitry is significantly larger than a second mass of conductive metal within the second set of underlying circuitry.

12. The method of claim 8, wherein the bottom-electrode metal layer and the top-electrode metal layer occurs with a single etching process.

13. The method of claim 8, wherein the two-terminal device is a non-volatile RAM cell.

14. A pattern of two-terminal devices comprising:
a first two-terminal device comprising a first top electrode and a first bottom electrode, wherein the first top electrode has the same width and depth as the first bottom electrode; and
a second two-terminal device comprising a second top electrode and a second bottom electrode, wherein the second top electrode has the same width and depth as the second bottom electrode.

15. The pattern of two-terminal devices of claim 14, wherein the first two-terminal device further comprises a first switching element between the first top electrode and first bottom electrode, wherein the second two-terminal device further comprises a second switching element between the first top electrode and first bottom electrode, and wherein the first switching element has been etched to the same height as the second switching element.

16. The pattern of two-terminal devices of claim 14, wherein the first bottom electrode connects the first two-terminal device to a first underlying circuitry, and wherein the second bottom electrode connects the second two-terminal device to a second underlying circuitry.

17. The pattern of two-terminal devices of claim 16, wherein the first underlying circuitry contains a first mass of conductive material, wherein the second underlying circuitry contains a second mass of conductive material, and wherein the first mass is significantly larger than the second mass.

18. The pattern of two-terminal devices of claim 14, wherein the first two-terminal device is a non-volatile RAM cell.

19. The pattern of two-terminal devices of claim 14, wherein the first two-terminal device is a resistor device.

20. The pattern of two-terminal devices of claim 14, wherein the first two-terminal device is a capacitor device.
